(19) United States
(12) Patent Application Publication
(10) Pub. No.: US 2026/0276756 A1
(43) Pub. Date: Sep. 17, 2026

(54) VAPOR CELL EXCITATION ASSEMBLY

(71) Applicant: Northrop Grumman Systems Corporation, Falls Church, VA (US)

(72) Inventors: Jonathan M. Wheeler, Woodland Hills, CA (US); A. Douglas Meyer, Woodland Hills, CA (US); Daniel A. Tazartes, West Hills, CA (US)

(21) Appl. No.: 19/054,950

(22) Filed: Feb. 17, 2025

(51) Int. Cl. G01R 33/26; G01R 33/032

(52) U.S. Cl. CPC G01R 33/26; G01R 33/032

(57) ABSTRACT

A vapor cell excitation assembly includes a cell wall, a first end cap coupled to a first end of the cell wall, and a second end cap coupled to a second end of the cell wall. As such, the cell wall, the first end cap, and the second end cap define a chamber therein. An alkali material is present within the chamber. Additionally, the vapor cell excitation assembly includes an optical fiber configured to transmit light into the cell wall, the first end cap, or the second end cap. In this respect, the light excites the alkali material such that droplets of the alkali material are desorbed from an inner surface of the cell wall, the first end cap, or the second end cap.

### FIELD

The present disclosure generally relates to vapor cells, and, more particularly, to a vapor cell excitation assembly, such as for use in atomic magnetometry and/or nuclear magnetic resonance (NMR) gyroscopy.

### BACKGROUND

In certain applications, such as atomic magnetometry, vapor cells are used in the detection of and/or measurement of the strength of magnetic fields. In general, a vapor cell is a container made of glass or another similar material in which an alkali material is present. When at ambient or room temperature, most of the alkali material is solid and adheres or otherwise clings to the inner surface of the container. In this respect, the alkali material must be excited, such as by heating the container, for the vapor cell to be of use in the detection or measurement of a magnetic field. When excited, the alkali material desorbs or otherwise releases from the inner surface of the container and vaporizes. Conventional vapor cell excitation assemblies or devices for exciting the alkali material rely on electric resistance heating to heat the glass container. However, electric resistance heating can interfere with the magnetic field being measured or detected, thereby reducing the sensitivity of the associated atomic magnetometer in which the vapor cell is incorporated.

Accordingly, an improved vapor cell excitation assembly would be welcomed in this technology domain.

### SUMMARY

Aspects and advantages of the technology will be set forth in part in the following description or may be obvious from the description, or may be learned through practice of the technology.

In one aspect, the present disclosure is directed to a vapor cell excitation assembly including a cell wall extending along a longitudinal centerline from a first end to a second end. Furthermore, the vapor cell excitation assembly includes a first end cap coupled to the first end of the cell wall and a second end cap coupled to the second end of the cell wall such that the cell wall, with the first end cap, and the second end cap define a chamber therein. An alkali material is present within the chamber. Additionally, the vapor cell excitation assembly includes an optical fiber configured to transmit light into the cell wall, the first end cap, or the second end cap. In this respect, the light excites the alkali material such that droplets of the alkali material are desorbed from an inner surface of the cell wall, the first end cap, or the second end cap.

In another aspect, the present subject matter includes an atomic magnetometer including a cell wall extending along a longitudinal centerline from a first end to a second end. The atomic magnetometer includes a first end cap coupled to the first end of the cell wall and a second end cap coupled to the second end of the cell wall such that the cell wall, the first end cap, and the second end cap define a chamber therein. An alkali material is present within the chamber. Moreover, the atomic magnetometer includes one or more lasers configured to pump the alkali material and probe a polarization state of the alkali material. In addition, the atomic magnetometer includes an optical fiber configured to transmit light into the cell wall, the first end cap, or the second end cap. As such, the light excites the alkali material such that droplets of the alkali material are desorbed from an inner surface of the cell wall, the first end cap, or the second end cap.

These and other features, aspects, and advantages of the present technology will become better understood with reference to the following description and appended claims. The accompanying drawings, which are incorporated in and constitute a part of this specification, illustrate embodiments of the technology and, together with the description, explain the principles of the technology.

### BRIEF DESCRIPTION OF THE DRAWINGS

A full and enabling disclosure of the present technology directed to one of ordinary skill in the art is set forth in the specification, which refers to the appended figures, in which:

FIG. 1 is a perspective view of one embodiment of a vapor cell excitation assembly in accordance with aspects of the present disclosure;

FIG. 2 is a cross-sectional view of the vapor cell excitation assembly taken generally about Line 2-2 in FIG. 1;

FIG. 3 is a cross-sectional view of the vapor cell excitation assembly taken generally about Line 3-3 in FIG. 1;

FIG. 4 is a diagrammatic, cross-sectional view of the vapor cell excitation assembly shown in FIG. 1;

FIG. 5 is a top view of the vapor cell excitation assembly shown in FIG. 1;

FIG. 6 is a diagrammatic, front view of the vapor cell excitation assembly shown in FIG. 1;

FIG. 7 is a cross-sectional view of another embodiment of a vapor cell excitation assembly in accordance with aspects of the present disclosure;

FIG. 8 is a diagrammatic, top view of the vapor cell excitation assembly shown in FIG. 7;

FIG. 9 is a cross-sectional view of a further embodiment of a vapor cell excitation assembly in accordance with aspects of the present disclosure;

FIG. 10 is a cross-sectional view of yet another embodiment of a vapor cell excitation assembly in accordance with aspects of the present disclosure; and

FIG. 11 is a diagrammatic side view of one embodiment of an atomic magnetometer in accordance with aspects of the present disclosure.

Repeat use of reference characters in the present specification and drawings is intended to represent the same or analogous features or elements of the present technology.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield still a further embodiment. Thus, it is intended that the present invention covers such modifications and variations as come within the scope of the appended claims and their equivalents.

As used herein, the term “and/or,” when used in a list of two or more items, means that any one of the listed items can be employed by itself, or any combination of two or more of the listed items can be employed. For example, if a composition or assembly is described as containing components A, B, and/or C, the composition or assembly can contain A alone; B alone; C alone; A and B in combination; A and C in combination; B and C in combination; or A, B, and C in combination.

In general, the present disclosure is directed to a vapor cell excitation assembly. More specifically, the vapor cell excitation assembly includes a cell wall extending along a longitudinal centerline from a first end to a second end. Moreover, the vapor cell assembly includes a first end cap coupled to the first end of the cell wall and a second end cap coupled to the second end of the cell wall. For example, in some embodiments, the cell wall and the first and second end caps are formed from a material, such as glass, quartz, or sapphire, that partially absorbs a selected wavelength of the light. The cell wall and the first and second end caps, in turn, define a chamber therein. Additionally, an alkali material, such as rubidium or potassium, is present within the chamber.

Furthermore, the vapor cell excitation assembly includes one or more optical fiber(s). In general, the optical fiber(s) is configured to transmit light into the cell wall, the first end cap, and/or the second end cap. More specifically, energy is supplied via optical fibers to the alkali atoms such that a fraction of the atoms in the alkali-material droplets have enough energy to desorb from the inner surface(s) of the cell wall and/or the first and/or second end cap(s). For example, in some embodiments, the light transmitted by the optical fiber(s) is absorbed by and heats the cell wall and/or the first and/or second end caps. In this respect, as the cell wall and/or the first and/or second end caps are heated, the thermal energy of the droplets of the alkali material increases. Once the droplets of the alkali material reach a sufficient thermal energy level, a fraction of the atoms in the droplets will have enough thermal energy to break the bonds holding them to the corresponding droplet or the inner surface(s) and vaporize. In other embodiments, energy from the light transmitted by the optical fiber(s) is transferred directly to the droplets of the alkali material present on the inner surface(s) of the cell wall and/or the first and/or second end caps. This, in turn, causes such droplets to desorb from the inner surface(s) via laser-induced atom desorption (LIAD).

The optical fiber(s), in turn, improves the operation of the disclosed vapor cell excitation assembly. More specifically, as described above, the optical fiber(s) transmits light into the cell wall, the first end cap, and/or the second end cap. This light, in turn, provides the energy to excite the alkali material such that a fraction of the atoms in the droplets of the alkali material desorb from the inner surface(s) of the cell wall and/or the first and/or second end caps and vaporizes. In this respect, the disclosed vapor cell excitation assembly does not interfere with the magnetic field being detected or measured because it relies on light and not electrical resistance to excite the alkali material. Moreover, the disclosed vapor cell excitation assembly does not use the light to heat the optical fiber(s) for conductive transfer to the cell wall, the first end cap, and/or the second end cap. Rather, all the light transmitted by the optical fiber(s) is pumped into the cell wall, the first end cap, and/or the second end cap where the heating occurs. This provides more efficient heating of the cell wall, the first end cap, and/or the second end cap and allows for LIAD. Thus, incorporating the disclosed vapor cell excitation assembly into an atomic magnetometer or other measurement device improves the sensitivity of the atomic magnetometer or other measurement device.

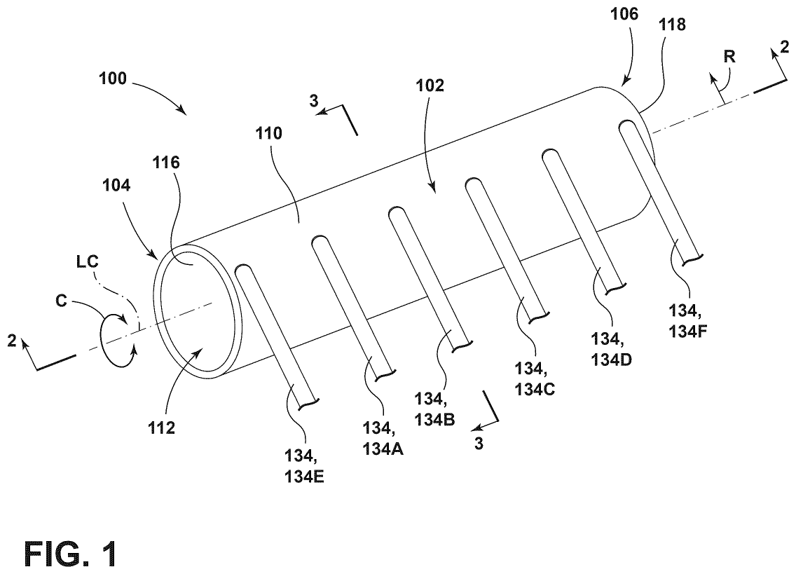

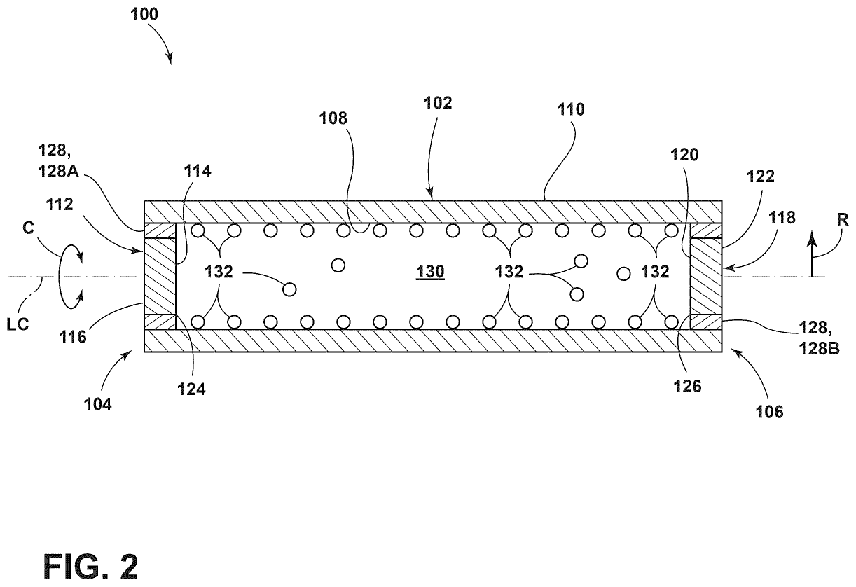

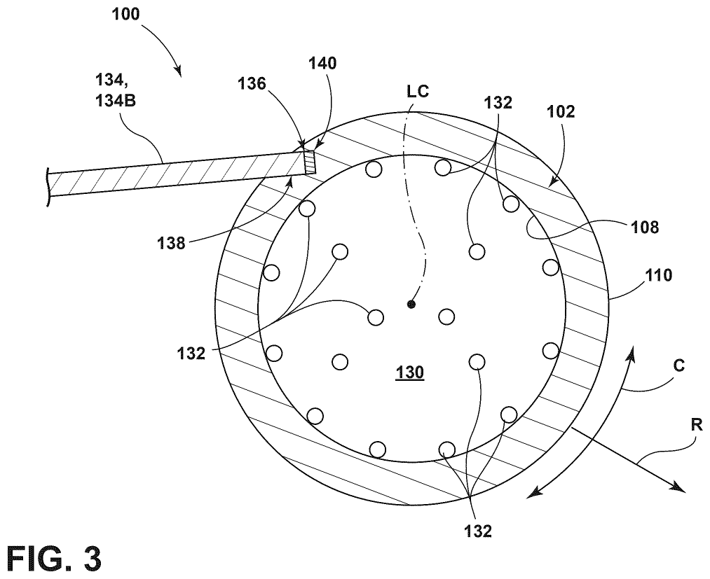

Referring now to the drawings, FIGS. 1-3 are differing views of one embodiment of a vapor cell excitation assembly 100 in accordance with aspects of the present disclosure. Specifically, FIG. 1 is a perspective view of the vapor cell excitation assembly 100. Furthermore, FIG. 2 is a cross-sectional view of the vapor cell excitation assembly 100 taken generally about Line 2-2 in FIG. 1. Additionally, FIG. 3 is a cross-sectional view of the vapor cell excitation assembly 100 taken generally about Line 3-3 in FIG. 1.

As shown in FIGS. 1-3, the vapor cell excitation assembly 100 includes a cell wall 102. In general, the cell wall 102 extends along a longitudinal centerline LC from a first end 104 to a second end 106. In several embodiments, the cell wall 102 is annular such that the cell wall 102 extends in a circumferential direction C around (i.e., circumferentially around) the longitudinal centerline LC. In such embodiments, the cell wall 102 includes an inner surface 108 and an outer surface 110 that is spaced apart from the inner surface 108 in a radial direction R. The radial direction R, in turn, extends radially outward from the longitudinal centerline LC. However, in alternative embodiments, the cell wall 102 may define any other suitable shape. For example, as will be described below, in some embodiments, the cell wall 102 may define a cuboid shape.

Furthermore, the vapor cell excitation assembly 100 includes a first end cap 112. More specifically, the first end cap 112 is coupled to the first end 104 of the cell wall 102. As shown, the first end cap 112 includes an inner surface 114 and an outer surface 116 that is spaced apart from the inner surface 114 along the longitudinal centerline LC.

Additionally, the vapor cell excitation assembly 100 includes a second end cap 118. More specifically, the second end cap 118 is coupled to the second end 106 of the cell wall 102. As shown, the second end cap 118 includes an inner surface 120 and an outer surface 122 that is spaced apart from the inner surface 120 along the longitudinal centerline LC.

The first and second end caps 112, 118 may have any suitable shapes. For example, in embodiments in which the cell wall 102 is annular, the first and second end caps 112, 118 may define a circular shape. In such embodiments, the first end cap 112 defines an outer circumference 124, and the second end cap 118 defines an outer circumference 126. However, in alternative embodiments, the first and second end caps 112, 118 may define any other suitable shapes, such as a rectangular shape when the cell wall 102 defines a cuboid shape.

In several embodiments, the vapor cell excitation assembly 100 may include a reflective coating 128. More specifically, the reflective coating 128 is positioned between the cell wall 102 and the outer circumference(s) 124, 126 of the first and/or second end caps 112, 118. For example, in the illustrated embodiment, a first reflective coating 128A is positioned between the cell wall 102 and the outer circumference 124 of the first end cap 112. Similarly, a second reflective coating 128B is positioned between the cell wall 102 and the outer circumference 126 of the second end cap 118. As will be described below, the first and second reflective coatings 128A, 128 may prevent light transmitted into the first and second end caps 112, 118, respectively, from leaking out. However, in alternative embodiments, the reflective coating 128 may be on the outside.

The cell wall 102, the first end cap 112, and the second end cap 118 may be formed from any suitable material through which light can travel. Specifically, in several embodiments, the cell wall 102, the first end cap 112, and the second end cap 118 may be formed from a material that absorbs a selected wavelength or range of wavelengths of the light. For example, the cell wall 102, the first end cap 112, and the second end cap 118 may be formed from borosilicate glass, quartz, and/or sapphire. Moreover, in some embodiments, the cell wall 102 and the first and second end caps 112, 118 may be formed from different materials. As will be described below, by absorbing a selected wavelength, light having the selected wavelength can heat the cell wall 102, the first end cap 112, and/or the second end cap 118.

In addition, the cell wall 102, the first end cap 112, and the second end cap 118 define a chamber 130 therein. More specifically, as shown in FIGS. 2 and 3, the inner surface 108 of the cell wall 102, the inner surface 114 of the first end cap 112, and the inner surface 120 of the second end cap 118 define the chamber 130. Thus, the chamber 130 extends outward from the longitudinal centerline LC in the radial direction R to the inner surface 108 of the cell wall 102. Moreover, the chamber 130 extends along the longitudinal centerline LC from the inner surface 114 of the first end cap 112 to the inner surface 120 of the second end cap 118.

Furthermore, the vapor cell excitation assembly 100 includes an alkali material 132 present within the chamber 130. In general, when the alkali material 132 within the chamber 130 is excited, the alkali material 132 vaporizes and, in certain applications, can be pumped and probed (e.g., with one or more lasers), such as to detect and/or measure the strength of a magnetic field. Thus, the alkali material 132 may be rubidium, potassium, or any suitable alkali material. In FIGS. 2 and 3, the alkali material 132 is in an unexcited state in which droplets of the alkali material 132 adhere to or otherwise cling to the inner surfaces 108, 114, 120 of the cell wall 102, the first end cap 112, and/or the second end cap 118, respectively.

Additionally, the vapor cell excitation assembly 100 includes one or more optical fibers 134. In general, each optical fiber 134 is configured to transmit light into the cell wall 102, the first end cap 112, or the second end cap 118. As will be described below, the light transmitted by the optical fiber(s) 134 excites the alkali material 132 such that droplets of the alkali material 132 are desorbed from the inner surfaces 108, 114, 120 of the cell wall 102, the first end cap 112, and/or the second end cap 118.

The optical fiber(s) 134 may have any suitable structure and/or configuration for transmitting light at a selected wavelength or range of wavelengths. For example, in some embodiments, the optical fiber(s) 134 may be slender, flexible glass or polymeric fibers capable of transmitting light therethrough. In other embodiments, the optical fiber(s) 134 may be a light pipe(s) or a liquid light guide(s).

The vapor cell excitation assembly 100 may include any suitable number of optical fibers 134. For example, as shown in FIG. 1, in the illustrated embodiment, the vapor cell excitation assembly 100 includes first, second, third, fourth, fifth, and sixth optical fibers 134A, 134B, 134C, 134D, 134E, 134F. Specifically, the first, second, third, and fourth optical fibers 134A, 134B, 134C, 134D are coupled to the cell wall 102. Conversely, the fifth optical fiber 134E is coupled to the first end cap 112, and the sixth optical fiber 134F is coupled to the second end cap 118. However, in alternative embodiments, the vapor cell excitation assembly 100 may include more or fewer optical fibers 134 so long as the vapor cell excitation assembly 100 includes at least one optical fiber 134.

In embodiments in which multiple optical fibers 134 are coupled to the cell wall 102, such optical fibers 134 may be spaced apart from each other along the longitudinal centerline LC. For example, as shown in FIG. 1, in the illustrated embodiment, the first optical fiber 134A is spaced apart from the second optical fiber 134B. Furthermore, the second optical fiber 134B, in turn, is spaced apart from the third optical fiber 134C. Additionally, the third optical fiber 134C, in turn, is spaced apart from the fourth optical fiber 134D. As will be described below, the number and spacing of the optical fibers 134 coupled to the cell wall 102 may be selected to ensure light travels through the entirety of the cell wall 102.

The optical fiber(s) 134 may be coupled to the cell wall 102, the first end cap 112, and/or the second end cap 118 in any suitable manner. For example, as shown in FIG. 3, in several embodiments, the cell wall 102 may define one or more holes 136 extending inward from the outer surface 110 of the cell wall 102. In this respect, an end 138 of each optical fiber 134 may be positioned within one of the holes 136, thereby coupling the corresponding optical fiber 134 to the cell wall 102. The optical fiber(s) 134 may be coupled to the first end cap 112 and/or the second end cap 118 in a similar manner.

In some embodiments, an index-matching material 140 (e.g., an index-matching gel) may be positioned within (and, e.g., fill) the hole(s) 136 between the cell wall 102 and the optical fiber(s) 134. In this respect, the index-matching material 140 may improve the transmission of light from the optical fiber(s) 134 to the cell wall 102.

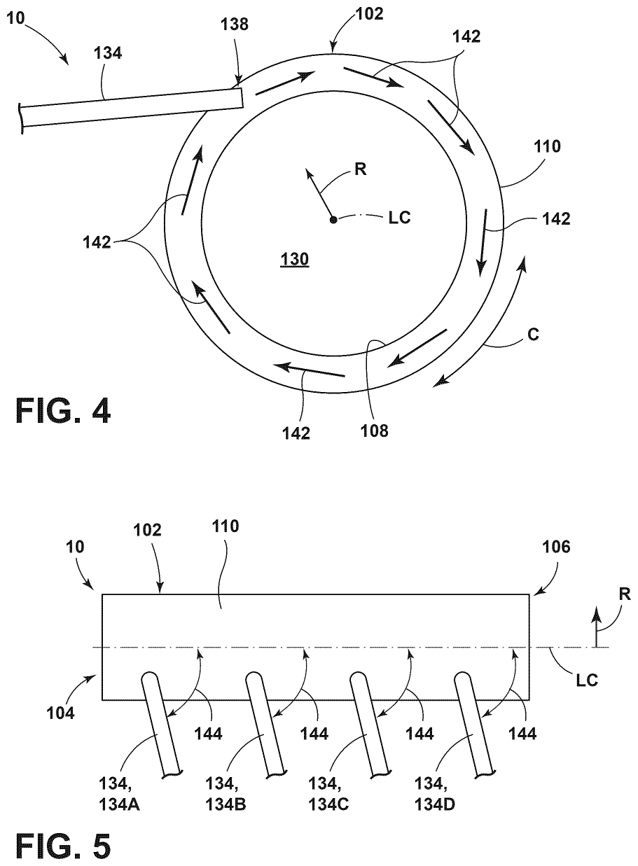

FIG. 4 is a diagrammatic, cross-sectional view of the vapor cell excitation assembly 100, particularly illustrating how the light travels through the cell wall 102 when the cell wall 102 is annular. More specifically, the optical fiber(s) 134 is configured to transmit light (indicated by arrows 142) into the cell wall 102 such that the light 142 travels through the cell wall 102 at least partially in the circumferential direction C. That is, the light 142 travels out of the end(s) 138 of the optical fiber(s) 134 and into the cell wall 102. The light 142 then travels at least partially in the circumferential direction C between the inner and outer surfaces 108, 110 of the cell wall 102 and around the longitudinal centerline LC by bouncing off the inner side of the outer surface 110 before eventually dissipating within the cell wall 102.

FIG. 5 is a top view of the vapor cell excitation assembly 100, particularly illustrating the cell wall 102. In several embodiments, the optical fiber(s) 134 coupled to the cell wall 102 may be oriented at an oblique angle relative to the longitudinal centerline LC such that the light travels through the cell wall 102 helically. For example, in the illustrated embodiment, as shown, an oblique angle 144 is defined between each of the first optical fiber 134A and the longitudinal centerline LC, the second optical fiber 134B and the longitudinal centerline LC, the third optical fiber 134C and the longitudinal centerline LC, and the fourth optical fiber 134D and the longitudinal centerline LC. Orienting each optical fiber 134 coupled to the cell wall 102 such that an oblique angle is defined relative to the longitudinal centerline LC causes the light to travel through the cell wall 102 helically. That is, such an orientation causes the light to travel both in the circumferential direction C and along the longitudinal centerline LC.

Moreover, by spacing the optical fibers 134 along the cell wall 102 such that each optical fiber 134 is positioned where the light transmitted into the cell wall 102 by the adjacent optical fiber 134 dissipates after traveling helically, light can travel through the entirety of the cell wall 102. For example, the first optical fiber 134A may be coupled to the cell wall 102 at the location where the light transmitted into the cell wall 102 by the second optical fiber 134B dissipates after traveling helically through the cell wall 102, and so on.

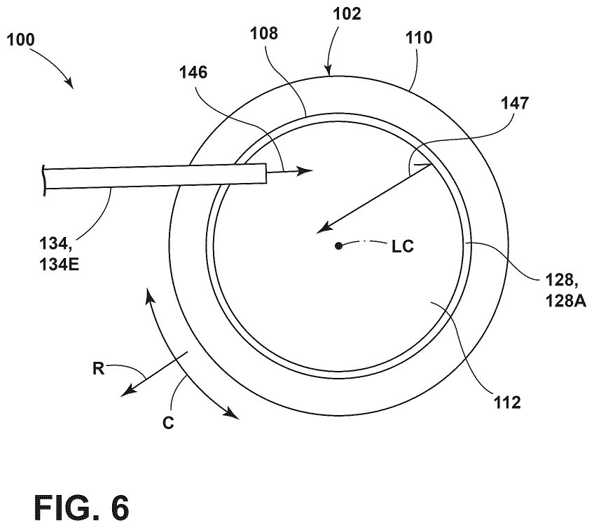

FIG. 6 is a diagrammatic, front view of the vapor cell excitation assembly 100, particularly illustrating the first end cap 112. As indicated above, one or more of the optical fibers 134 may be coupled to the first and/or second end caps 112, 118. In such configurations, the optical fiber(s) 134 is configured to transmit light into the first and/or second end caps 112, 118. Thus, the light can travel through the first and/or second end caps 112, 118 and is reflected by the reflective coating(s) 128. For example, in the illustrated embodiment, the fifth optical fiber 134E may transmit light (indicated by arrow 146) into the first end cap 112. The light 146 travels through the first end cap 112 and is then reflected and redirected by the first reflective coating 128A as indicated by arrow 147. The reflected and redirected light 147 travels through the first end cap 112 in a different direction before being reflected and redirected by the first reflective coating 128A again, and so on. After several reflections and redirections, the light will eventually move throughout the first end cap 112. The sixth optical fiber 134F may transmit light through the second end cap 118 in a similar manner.

In several embodiments, the light transmitted by the optical fiber(s) 134 heats the cell wall 102 and/or the first and/or second end caps 112, 118 to excite the alkali material 132. More specifically, the optical fiber(s) 134 may transmit light at a selected wavelength that can be absorbed by the cell wall 102 and/or the first and/or second end caps 112, 118. The absorbed light heats the cell wall 102 and/or the first and/or second end caps 112, 118. This, in turn, increases the thermal energy of the droplets of the alkali material 132 adhered to the inner surface(s) 108, 114, 120 of the cell wall 102 and/or the first and/or second end caps 112, 118. Once the droplets of the alkali material 132 reach a sufficient thermal energy level, such droplets will desorb from the inner surface(s) 108, 114, 120 and vaporize.

In other embodiments, the light transmitted by the optical fiber(s) 134 may excite the alkali material 132 via laser-induced atom desorption (LIAD). More specifically, the optical fiber(s) 134 may transmit light at a selected wavelength such that the light travels through the cell wall 102 and/or the first and/or second end caps 112, 118 is absorbed by the droplets of the alkali material 132 adhered to the inner surfaces 108, 114, 120 thereof in a manner analogous to the photoelectric effect. Exciting the alkali material 132 via LIAD results in reduced heating of the cell wall 102 and/or the first and/or second end caps 112, 118. Thus, LIAD can provide excitation of the alkali material 132 with reduced energy consumption.

The optical fiber(s) 134 improves the operation of the vapor cell excitation assembly 100. More specifically, as described above, the optical fiber(s) 134 transmits light into the cell wall 102, the first end cap 112, and/or the second end cap 118. This light, in turn, provides the energy to excite the alkali material 132 such that the droplets of the alkali material 132 desorb from the inner surface(s) 108, 114, 120 of the cell wall 102 and/or the first and/or second end caps 112, 118 and vaporizes. In this respect, the vapor cell excitation assembly 100 does not interfere with the magnetic field being detected or measured because it relies on light and not electrical resistance to excite the alkali material 132. Thus, incorporating the vapor cell excitation assembly 100 into an atomic magnetometer or other measurement device improves the sensitivity of the atomic magnetometer or other measurement device.

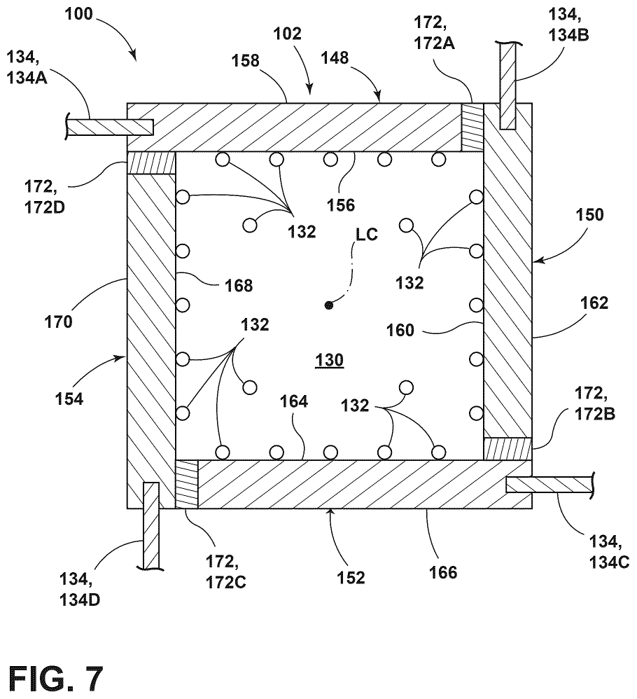

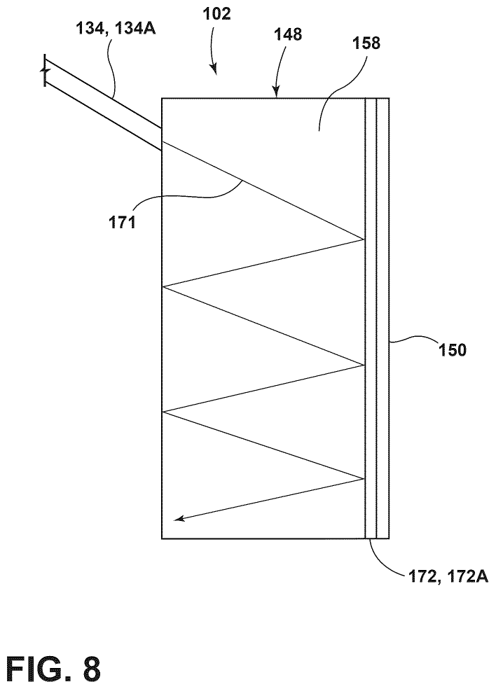

FIGS. 7 and 8 are differing views of another embodiment of the vapor cell excitation assembly 100 in accordance with aspects of the present disclosure. Specifically, FIG. 7 is a cross-sectional view of the vapor cell excitation assembly 100. Moreover, FIG. 8 is a diagrammatic, top view of the vapor cell excitation assembly 100.

More specifically, the vapor cell excitation assembly 100 shown in FIGS. 7 and 8 is configured similarly to the vapor cell excitation assembly 100 shown in FIGS. 1-6. For example, like the vapor cell excitation assembly 100 of FIGS. 1-6, the vapor cell excitation assembly 100 shown in FIGS. 7 and 8 includes the cell wall 102, the first end cap 112, the second end cap 118 (not shown in FIGS. 7 and 8 for clarity), the chamber 130, the alkali material 132, and the optical fiber(s) 134.

However, unlike the vapor cell excitation assembly 100 of FIGS. 1-6, the cell wall 102 of the vapor cell excitation assembly 100 shown in FIGS. 7 and 8 defines a cuboid shape. In this respect, the cell wall 102 includes first, second, third, and fourth planar cell walls 148, 150, 152, 154 arranged relative to each other such that a cuboid shape is defined. Specifically, as shown, the first planar cell wall 148 includes an inner surface 156 and an outer surface 158. Similarly, the second planar cell wall 150 includes an inner surface 160 and an outer surface 162. Moreover, the third planar cell wall 152 includes an inner surface 164 and an outer surface 166. In addition, the fourth planar cell wall 154 includes an inner surface 168 and an outer surface 170. Thus, the chamber 130 is defined between the inner surface 156 of the first planar cell wall 148, the inner surface 160 of the second planar cell wall 150, the inner surface 164 of the third planar cell wall 152, the inner surface 168 of the fourth planar cell wall 154, the inner surface 114 (not shown in FIGS. 7 and 8 for clarity) of the first end cap 112, and the inner surface 120 (not shown in FIGS. 7 and 8 for clarity) of the second end cap 118.

In some embodiments, the vapor cell excitation assembly 100 may include a reflective coating 172 positioned between adjacent planar cell walls. For example, as shown in FIG. 7, in the illustrated embodiment, a first reflective coating 172A is positioned between the first and second planar cell walls 148, 150. Furthermore, a second reflective coating 172B is positioned between the second and third planar cell walls 150, 152. Additionally, a third reflective coating 172C is positioned between the third and fourth planar cell walls 152, 154. Moreover, a fourth reflective coating 172D is positioned between the fourth and first planar cell walls 154, 148.

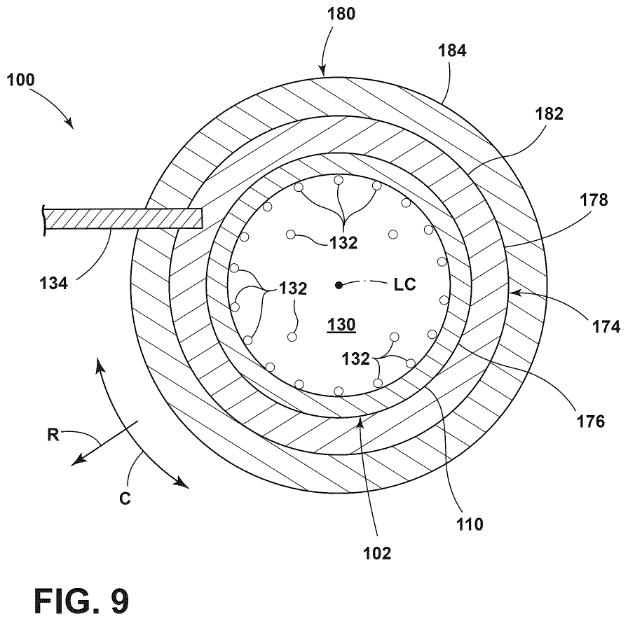

Furthermore, in the embodiment shown in FIG. 7, the first, second, third, and fourth optical fibers 134A, 134B 134C, 134D are coupled to the cell wall 102. More specifically, as shown, the first optical fiber 134A is coupled to the first planar cell wall 148. In this respect, the first optical fiber 134A is configured to transmit light into the first planar cell wall 148, which may be reflected off the first reflective coating 172A. For example, as shown in FIG. 8, the first optical fiber 134A may emit light (indicated by arrow 171) into the first planar cell wall 148 for reflection off the first reflective coating 172A. This, in turn, redirects the light within the first planar cell wall 148 for another reflection and redirection, and so on. Additionally, as shown in FIG. 7, the second optical fiber 134B is coupled to the second planar cell wall 150. As such, the second optical fiber 134B is configured to transmit light into the second planar cell wall 150, which may be reflected off the second reflective coating 172B. Moreover, the third optical fiber 134C is coupled to the third planar cell wall 152. Thus, the third optical fiber 134C is configured to transmit light into the third planar cell wall 152, which may be reflected off the third reflective coating 172C. In addition, the fourth optical fiber 134D is coupled to the fourth planar cell wall 154. In this respect, the fourth optical fiber 134D is configured to transmit light into the fourth planar cell wall 154, which may be reflected off the fourth reflective coating 172D. FIG. 9 is a cross-sectional view of a further embodiment of the vapor cell excitation assembly 100 in accordance with aspects of the present disclosure. More specifically, the vapor cell excitation assembly 100 shown in FIG. 9 is configured similarly to the vapor cell excitation assembly 100 shown in FIGS. 1-6. For example, like the vapor cell excitation assembly 100 of FIGS. 1-6, the vapor cell excitation assembly 100 shown in FIG. 9 includes the cell wall 102, the first end cap 112 (not shown in FIG. 9 for clarity), the second end cap 118 (not shown in FIG. 9 for clarity), the chamber 130, the alkali material 132, and the optical fiber(s) 134.

However, unlike the vapor cell excitation assembly 100 of FIGS. 1-6, the vapor cell excitation assembly 100 shown in FIG. 9 includes an optically active sheath 174. More specifically, the optically active sheath 174 is positioned around the outer surface 110 of the cell wall 102. That is, the optically active sheath 174 is positioned circumferentially around the exterior of the cell wall 102. Furthermore, as shown, the optically active sheath 174 extends in the radial direction R from an inner surface 176 to an outer surface 178. In this respect, the inner surface 176 of the optically active sheath 174 is in contact or coupled to the outer surface 110 of the cell wall 102.

Additionally, the optical fiber(s) 134 may be coupled to the optically active sheath 174. More specifically, the optical fiber(s) 134 may transmit light into the optical active sheath 174 such that a portion of the light is absorbed by the optically active sheath 174 and reradiated into the cell wall 102 as an amplified spontaneous emission of light. The amplified spontaneous emission of light, in turn, may heat the cell wall 102, thereby exciting the alkali material 132 adhered to the inner surface 108 thereof. As shown, in the illustrated embodiment, the optical fiber(s) 134 is coupled to the outer surface 178 of the optically active sheath 174.

The optically active sheath 174 may be formed of any suitable materials that allow the optically active sheath 174 to function as described above. For example, in several embodiments, the optically active sheath 174 may be doped with erbium. For example, when the optically active sheath 174 is doped with erbium, the optical fiber(s) 134 may transmit light into the optically active sheath 174 having a wavelength in the range of 1450-1500 nm, which corresponds to the absorption spectrum of erbium. The optically active sheath 174, in turn, may reradiate light having a wavelength in the range of 1525-1575 nm into the cell wall 102. In such embodiments, the cell wall 102 may be doped with a suitable material to allow for the absorption of the reradiated light having a wavelength in the range of 1525-1575 nm.

Additionally, in some embodiments, the optically active sheath 174 may be non-uniformly doped with erbium. Non-uniform erbium doping can vary the amount of the light absorbed by the optically active sheath 174 and reradiated into the cell wall 102, such as to prevent cold spots along the cell wall 102 where the alkali material is not desorbed.

Moreover, the vapor cell excitation assembly 100 shown in FIG. 7 includes a reflective outer layer 180. More specifically, in the illustrated embodiment, the reflective outer layer 180 is positioned around the outer surface 178 of the optically active sheath 174. That is, the reflective outer layer 180 is positioned circumferentially around the exterior of the optically active sheath 174 to prevent light from traveling outward from the optically active sheath 174 in the radial direction R. Furthermore, as shown, the reflective outer layer 180 extends in the radial direction R from an inner surface 182 to an outer surface 184. In this respect, the inner surface 182 of the reflective outer layer 180 is in contact or coupled to the outer surface 178 of the optically active sheath 174. In some embodiments, the reflective outer layer 180 may be a foil layer. In some embodiments, another reflective layer may optionally be positioned between the inner surface 176 of the optically active sheath 174 and the cell wall 110.

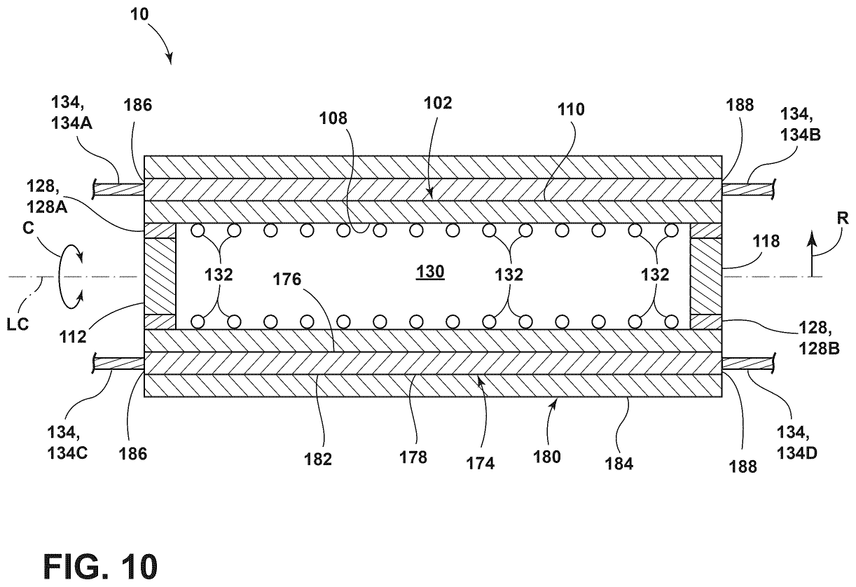

FIG. 10 is a cross-sectional view of yet another embodiment of the vapor cell excitation assembly 100 in accordance with aspects of the present disclosure. More specifically, the vapor cell excitation assembly 100 shown in FIG. 10 is configured similarly to the vapor cell excitation assembly 100 shown in FIG. 9. For example, like the vapor cell excitation assembly 100 of FIG. 9, the vapor cell excitation assembly 100 shown in FIG. 10 includes the cell wall 102, the first end cap 112, the second end cap 118, the chamber 130, the alkali material 132, the optical fiber(s) 134, the optically active sheath 174, and the reflective outer layer 180.

However, unlike the vapor cell excitation assembly 100 of FIG. 9, in the vapor cell excitation assembly 100 shown in FIG. 10, the optical fiber(s) 134 are coupled to the end surfaces of the optically active sheath 174. More specifically, as shown, the first optical fiber 134A is coupled to a first end surface 186 of the optically active sheath 174. In this respect, the first optical fiber 134A is configured to transmit light into the optically active sheath 174 through the first end surface 186. Additionally, the second optical fiber 134B is coupled to a second end surface 188 of the optically active sheath 174. The second end surface 188, in turn, is spaced apart from the first end surface 186 along the longitudinal centerline LC. Thus, the inner and outer surfaces 176, 178 of the optically active sheath 174 extend along the longitudinal direction LC between the first and second end surface 186, 188. As such, the second optical fiber 134B is configured to transmit light into the optically active sheath 174 through the second end surface 188. Moreover, the third optical fiber 134C is coupled to the first end surface 186 of the optically active sheath 174. Thus, the third optical fiber 134C is configured to transmit light into the optically active sheath 174 through the first end surface 186. In addition, the fourth optical fiber 134D is coupled to the second end surface 188 of the optically active sheath 174. As such, the fourth optical fiber 134D is configured to transmit light into the optically active sheath 174 through the second end surface 188.

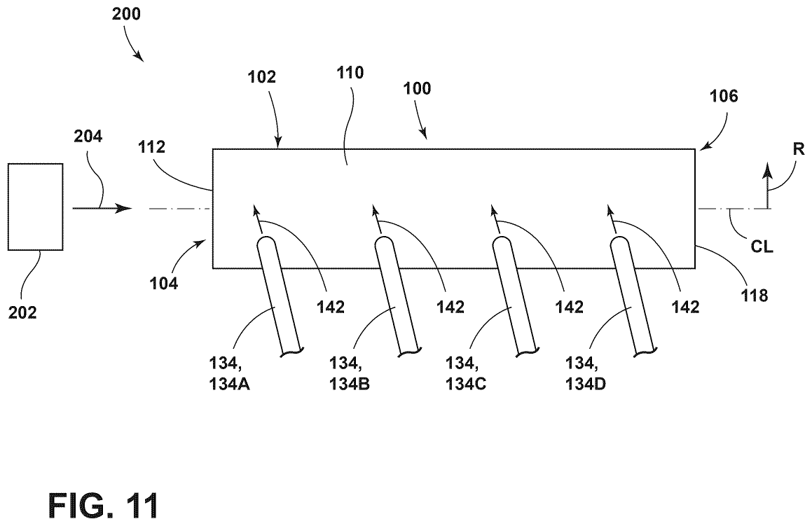

FIG. 11 is a diagrammatic side view of one embodiment of an atomic magnetometer 200 in accordance with aspects of the present disclosure. As shown, the atomic magnetometer 200 includes the vapor cell excitation assembly 100 described above with reference to FIGS. 1-9. Thus, the atomic magnetometer 200 includes the cell wall 102 extending along the longitudinal centerline LC from the first end 104 to the second end 106. Furthermore, the atomic magnetometer 200 includes the first end cap 112 coupled to the first end 104 of the cell wall 102 and the second end cap 118 coupled to the second end 106 of the cell wall 102. In this respect, the cell wall 102, the first end cap 112, and the second end cap 118 define the chamber 130, with the alkali material 132 (FIG. 2) present therein. Additionally, the atomic magnetometer 200 includes one or more optical fiber(s) 134 (e.g., the first, second, third, and fourth optical fibers 134A-D). The optical fiber(s) 134 is configured to transmit the light 142 into the cell wall 102 and/or the first and/or second end caps 112, 118. As described above, the light 142 transmitted by the optical fiber(s) 134 excites the alkali material 132 (e.g., by heating the cell wall 102 and/or the first and/or second end caps 112, 118, or via LIAD). This, in turn, desorbs the droplets of the alkali material 132 from the inner surface(s) 108, 114, 120 of the cell wall 102 and/or the first and/or second end caps 112, 118.

Moreover, the atomic magnetometer 200 includes one or more lasers 202 configured to pump the alkali material 132 and probe the polarization state of the alkali material 132. For example, the laser(s) 202 may be configured to emit a laser beam or photons of light (indicated by arrow 204) at a first wavelength for pumping the alkali material 132 (e.g., 795 nm for rubidium). Furthermore, the laser(s) 202 may be configured to emit the laser beam 204 at a second wavelength for probing the alkali material 132 (e.g., 780 nm for rubidium). In this respect, the optical fiber(s) 134 is configured to transmit the light 142 at a different wavelength (e.g., 1450-1500 nm) than the laser beams emitted by the laser(s) 202 when pumping the alkali material 132 and probing polarization state of the alkali material 132.

In addition, the vapor cell excitation assembly 100 described above with reference to FIGS. 1-9 may be incorporated into or otherwise used in other applications, such as nuclear magnetic resonance (NMR) gyroscopy.

This written description uses examples to disclose the technology to enable any person skilled in the art to practice the technology, including making and using any devices or systems and performing any incorporated methods. The patentable scope of the technology is defined by the claims and may include other examples that occur to those skilled in the art. Such other examples are intended to be within the scope of the claims if they include structural elements that do not differ from the literal language of the claims, or if they include equivalent structural elements with insubstantial differences from the literal language of the claims.

1. A vapor cell excitation assembly, comprising:
a cell wall extending along a longitudinal centerline from a first end to a second end;
a first end cap coupled to the first end of the cell wall;
a second end cap coupled to the second end of the cell wall such that the cell wall, the first end cap, and the second end cap define a chamber therein;
an alkali material present within the chamber; and
an optical fiber configured to transmit light into the cell wall, the first end cap, or the second end cap,
wherein the light excites the alkali material such that droplets of the alkali material are desorbed from an inner surface of the cell wall, the first end cap, or the second end cap.

2. The vapor cell excitation assembly of claim 1, wherein the cell wall, the first end cap, and the second end cap are formed from a material that absorbs a selected wavelength of the light.

3. The vapor cell excitation assembly of claim 1, wherein:
the cell wall is annular such that the cell wall extends in a circumferential direction around the longitudinal centerline; and
the optical fiber is configured to transmit the light into the cell wall such that the light travels through the cell wall at least partially in the circumferential direction.

4. The vapor cell excitation assembly of claim 3, wherein:
the cell wall defines a hole extending inward from an outer surface of the cell wall; and
an end of the optical fiber is positioned within the hole.

5. The vapor cell excitation assembly of claim 4, further comprising:
an index-matching material positioned within the hole between the cell wall and the optical fiber.

6. The vapor cell excitation assembly of claim 3, wherein the optical fiber is oriented at an oblique angle relative to the longitudinal centerline such that the light travels through the cell wall helically.

7. The vapor cell excitation assembly of claim 3, wherein the optical fiber corresponds to a first optical fiber, the vapor cell excitation assembly further comprising:
a second optical fiber spaced apart from the first optical fiber along the longitudinal centerline, the second optical fiber configured to transmit the light into the cell wall such that the light travels through the cell wall at least partially in the circumferential direction.

8. The vapor cell excitation assembly of claim 1, further comprising:
a reflective coating positioned between the cell wall and an outer circumference of one of the first end cap or the second end cap,
wherein the optical fiber is coupled to the one of the first end cap or the second end cap and is configured to transmit the light into the one of the first end cap or the second end cap such that the light travels through the one of the first end cap or the second end cap and is reflected by the reflective coating.

9. The vapor cell excitation assembly of claim 1, wherein:
the cell wall comprises first, second, third, and fourth planar cell walls defining a cuboid shape;
the optical fiber corresponds to a first optical fiber coupled to the first planar cell wall; and
the vapor cell excitation assembly further comprises:
a second optical fiber coupled to the second planar cell wall;
a third optical fiber coupled to the third planar cell wall; and
a fourth optical fiber coupled to the fourth planar cell wall.

10. The vapor cell excitation assembly of claim 9, further comprising:
a first reflective coating positioned between the first and second planar cell walls;
a second reflective coating positioned between the second and third planar cell walls;
a third reflective coating positioned between the third and fourth planar cell walls; and
a fourth reflective coating positioned between the fourth and first planar cell walls.

11. The vapor cell excitation assembly of claim 1, further comprising:
an optically active sheath positioned around an outer surface of the cell wall,
wherein the optical fiber is coupled to the optically active sheath to transmit the light into the optical active sheath such that a portion of the light is absorbed by the optically active sheath and reradiated into the cell wall as an amplified spontaneous emission of light.

12. The vapor cell excitation assembly of claim 11, further comprising:
a reflective outer layer positioned around an outer surface of the optically active sheath.

13. The vapor cell excitation assembly of claim 11, wherein the optical fiber is coupled to an outer surface of the optically active sheath.

14. The vapor cell excitation assembly of claim 11, wherein the optical fiber is coupled to an end surface of the optically active sheath.

15. The vapor cell excitation assembly of claim 14, wherein the optical fiber corresponds to a first optical fiber and the end surface corresponds to a first end surface, the vapor cell excitation assembly further comprising:
a second optical fiber coupled to a second end surface of the optically active sheath, the second end surface spaced apart from the first end surface along the longitudinal centerline.

16. The vapor cell excitation assembly of claim 11, wherein the optically active sheath is doped with erbium.

17. The vapor cell excitation assembly of claim 1, wherein the optical fiber is configured to transmit the light such that the light is absorbed by and heats the cell wall, the first end cap, or the second end cap.

18. The vapor cell excitation assembly of claim 1, wherein the optical fiber is configured to transmit the light such that energy from the light is transferred to the droplets of the alkali material via laser-induced atom desorption.

19. An atomic magnetometer, comprising:
a cell wall extending along a longitudinal centerline from a first end to a second end;
a first end cap coupled to the first end of the cell wall;
a second end cap coupled to the second end of the cell wall such that the cell wall, the first end cap, and the second end cap define a chamber therein;
an alkali material present within the chamber;
one or more lasers configured to pump the alkali material and probe a polarization state of the alkali material; and
an optical fiber configured to transmit light into the cell wall, the first end cap, or the second end cap,
wherein the light excites the alkali material such that droplets of the alkali material are desorbed from an inner surface of the cell wall, the first end cap, or the second end cap.

20. The atomic magnetometer of claim 19, wherein the optical fiber is configured to transmit the light at a different wavelength than the one or more lasers are configured to emit when pumping the alkali material and probing the polarization state of the alkali material.
